(19) United States
(12) Patent Application Publication
(10) Pub. No.: US 2015/0355382 A1
(43) Pub. Date: Dec. 10, 2015

(54) HARD ANTI-REFLECTIVE COATINGS AND MANUFACTURING AND USE THEREOF

(71) Applicant: SCHOTT AG, Mainz (DE)

(72) Inventors: Christian Henn, Frei-Laubersheim (DE); Thorsten Damm, Nieder-Olm (DE); Andreas Hahn, Hochstetten-Dhaun (DE); Ulf Brauneck, Gross-Umstadt (DE)

(21) Appl. No.: 14/678,302

(22) Filed: Apr. 3, 2015

(30) Foreign Application Priority Data
Apr. 3, 2014 (DE) 102014104798.2

(51) Int. Cl. G02B 1/115; C23C 14/18; C23C 14/34

(52) U.S. Cl. CPC G02B 1/115; C23C 14/34; C23C 14/185

(57) ABSTRACT

A coated substrate is provided with a scratch-resistant anti-reflective coating. The anti-reflective coating is designed as an optical interference coating that has at least two low refractive index layers and at least one high refractive index layer. The high refractive index layer is a transparent hard material layer and includes crystalline aluminum nitride with a hexagonal crystal structure with a (001) preferred orientation. The low refractive index layers include SiO2. The low refractive index layers and high refractive index layers are arranged alternately.

### CROSS REFERENCE TO RELATED APPLICATIONS

This application claims benefit under 35 U.S.C. §119(a) of German Patent Application No. 102014104798.2 filed Apr. 3, 2014, the entire contents of which are incorporated herein by reference.

### BACKGROUND

1. Field of the Disclosure

The invention relates to a coated substrate having an anti-reflective coating. More particularly, the invention relates to a coated substrate comprising an anti-reflective coating in form of an optical interference coating. The invention also relates to a method for producing such a coating and to the use of a substrate comprising such a coating.

2. Description of Related Art

Optical interference coatings are used as anti-reflective coatings. Depending on the particular use or application field, these coatings will be exposed to different degrees of mechanical stress. If such coatings are for example used as watch glasses, viewing windows of civil and military vehicles, cooktops, or display covers such as touch display cover glasses, they need to exhibit high mechanical resistance, in particular high scratch resistance, in addition to reducing reflections.

Hard coatings in form of dual material systems are known from prior art. Such coatings mostly include oxides and nitrides of elements chromium, silicon, titanium, or zirconium. Although such coatings have a high hardness and mechanical strength, they are not or not sufficiently transparent to be useful in an optical interference system that has an anti-reflective effect, i.e. is intended to prevent reflections.

Patent application DE 10 2011 012 160 describes layer systems for reducing reflection of watch glasses. In order to increase the mechanical strength of the coatings, a Si3N4 layer which is additionally doped with aluminum is used as a high refractive index layer. The mechanical resistance of such a coating can be assessed from the anti-reflective performance of a substrate coated accordingly before and after a mechanical stress test. Following a mechanical stress test, the coated substrates as described in DE 10 2011 012 160 exhibit higher reflectance than before the stress test. The reflectance after the stress test is reduced by 50% as compared to the reflectance of the non-coated substrate.

Moreover, an increase in system hardness by increasing the thickness of the individual layers may be associated with a loss in anti-reflective performance, since the anti-reflective effect is reduced as layer thickness increases for a constant number of layers.

### SUMMARY

Therefore, an object of the present invention is to provide a coating and a coated substrate which exhibit high mechanical resistance in addition to a good anti-reflective effect. Another object of the invention is to provide a method for producing such a coating.

The substrate coated according to the invention comprises a coating that prevents reflections and which will be referred to as an anti-reflective coating below. Here, the anti-reflective coating is designed as an optical interference coating including a plurality of dielectric layers. The layer system of the coating comprises alternating low refractive index layers and high refractive index layers and is defined by at least two low refractive index layers and at least one high refractive index layer. The high refractive index layer is disposed between the two low refractive index layers. The uppermost dielectric layer is a low refractive index layer. Uppermost layer refers to that layer which has the greatest distance to the substrate. Accordingly, the lowermost layer of the coating is disposed directly on the substrate.

Preferably, the low refractive index layers have a refractive index ranging from 1.3 to 1.6, in particular from 1.45 to 1.5, at a wavelength of 550 nm. In this manner, a high anti-reflective effect can be achieved.

The low refractive index layers comprise SiO2. According to one embodiment, the low refractive index layers consist of SiO2 or of doped SiO2. In particular, the doped SiO2 is SiO2 doped with one or more oxides, nitrides, carbides, and/or carbonitrides of elements selected from a group comprising aluminum, boron, zirconium, titanium, chromium, and carbon. Alternatively or additionally, the low refractive index layer may contain N2. Preferably, the doped SiO2 is an aluminum-doped SiO2 with silicon contents ranging from 1 to 99 wt %, preferably from 85 to 95 wt %.

The coating may comprise a plurality of low refractive index layers of the same composition. Alternatively, the individual low refractive index layers of the coating may have different compositions.

The high refractive index layer or layers of the coating are provided in form of transparent hard material layers. The high refractive index layer, also referred to as hard material layer below, includes crystalline aluminum nitride having a hexagonal crystal structure that exhibits a predominant (001) preferred orientation. According to the invention, the proportion of AlN in the hard material layer is greater than 50 wt %.

Mechanical resistance of the coating is ensured by the high refractive index hard material layer. Surprisingly, the inventors have found that a particularly scratch-resistant coating which is furthermore resistant to wearing and polishing stress can be obtained when the AlN of the hard material layer is crystalline or at least substantially crystalline and has a hexagonal crystal structure. In particular, the AlN layer has a degree of crystallization of at least 50%.

This is surprising since usually it is assumed that due to the lack of crystallites amorphous coatings have a lower surface roughness than corresponding crystalline coatings. A low roughness of a layer is associated with a lower susceptibility to occurrence of defects such as those which are for example caused by the friction of a foreign body on the surface of the coating. However, the coating of the invention not only exhibits high scratch resistance but also enhanced resistance to environmental influences and polishing and wearing stress. For example, the hard material layer exhibits high chemical resistance to cleaning agents and detergents. Moreover, despite of its crystalline structure the coating of the invention is transparent for light of wavelengths in the visible and infrared spectral range, so that the coating is visually unobtrusive and can be used, for example, in optical components and as a coating for cooktops. In particular, the coating has a transmittance for visible light of at least 50%, preferably at least 80%, based on standard illuminant C, and a transmittance for infrared light of at least 50%, preferably at least 80%. Furthermore, the coating may exhibit a static friction μ to metallic bodies of μ<0.5, preferably μ<0.25.

In one embodiment, the hard material layer has a refractive index in a range from 1.8 to 2.3, preferably in a range from 1.95 to 2.1, at a wavelength of 550 nm.

In order to allow to use the high refractive index layer together with low refractive index layers in an optical interference system, the high refractive index layer has to exhibit sufficient transmittance. High transmittance of the high refractive index layer can in particular be achieved due to the small size of the individual crystallites. For example scattering effects are avoided due to the small size. In one embodiment of the invention, the average crystallite size is at most 25 nm, preferably at most 15 nm, and more preferably from 5 to 15 nm. A further advantage of the small crystallite size is a higher mechanical resistance of the layer containing the crystallites. For example, larger crystallites often have an offset in their crystal structure, which adversely affects mechanical resistance.

The AlN crystallites in the hard material layer have a hexagonal crystal structure with a predominant (001) preferred orientation, i.e. in parallel to the substrate surface. In a crystal structure that exhibits a preferred orientation, one of the symmetry orientations of the crystal structure is preferably adopted by the crystallites. Within the context of the invention, an AlN crystal structure having a (001) preferred orientation in particular refers to a crystal structure which exhibits a maximum reflection in a range between 34° and 37° in an XRD spectrum of a X-ray diffraction measurement (grazing incidence measurement: GIXRD). The reflection in this range can be associated with an AlN crystal structure having a (001) preferred orientation.

Surprisingly, it was found that hard material layers according to the invention having a predominant (001) preferred orientation exhibit a higher modulus of elasticity and a greater hardness than hard material layers having an identical or similar composition but without (001) preferred orientation.

The high modulus of elasticity of the embodiment exhibiting a predominant (001) preferred orientation may be explained by the fact that the modulus of elasticity of a crystalline material depends on the preferred orientation thereof. So, in the high refractive index hard material layer of the coating, the modulus of elasticity is greatest in parallel to the substrate surface. In one embodiment of the invention, at a test load of 10 mN the hard material layers have a modulus of elasticity in parallel to the substrate surface in a range from 80 to 250 GPa, preferably in a range from 110 to 200 GPa.

The scratch resistance of a coating not only depends on the hardness but also depends on how well the individual layers or sublayers adhere to each other and how well the coating adheres to the substrate. Furthermore, if the individual layers of the coating and/or the substrate have different coefficients of thermal expansion, this may cause tensions to build up in the coating and spalling of the coating.

The abrasion resistance of the high refractive index hard material layer and hence also that of the coating according to the invention further depends on the ratio of hardness to the modulus of elasticity of the respective layer. Preferably, therefore, the high refractive index layers have a ratio of hardness to the modulus of elasticity of at least 0.08, preferably 0.1, more preferably greater than 0.1. This may be achieved by the (001) preferred orientation. Layers of similar composition but with different preferred orientation exhibit comparatively low values in a range from 0.06 to 0.08.

The properties described above can particularly be achieved when the (001) preferred orientation of the crystal structure is most pronounced as compared to the (100) and (101) orientations. In addition, in one embodiment of the invention the proportion of (100) oriented crystal structures is greater than the proportion of (101) oriented crystal structures.

The proportion of the crystal structure having a (001) preferred orientation may be determined as follows:

acquiring a grazing incidence XRD (GIXRD) spectrum of the respective layer, i.e. thin film X-ray diffraction;

determining the maximum intensity of the corresponding (001) reflection 1(001) in a range between 34° and 37°;

determining the maximum intensity of the (100) reflection 1(100) in a range between 32° and 34°; and

determining the maximum intensity of the (101) reflection 1(101) in a range between 37° and 39°.

The proportions of the crystal structure exhibiting the (001) preferred orientation, x(001) and y(001), are calculated as follows:

x(001)=I(001)/(I(001)+I(100))

and y(001)=I(001)/(I(001)+I(101)).

A proportion of x(001) of greater than 0.5, preferably greater than 0.6, and more preferably greater than 0.75 and/or a proportion of y(001) of greater than 0.5, preferably greater than 0.6, and more preferably greater than 0.75 has been found particularly advantageous.

In one embodiment of the invention, the proportion of oxygen in the high refractive index layer is at most 10 at %, preferably at most 5 at %, and more preferably at most 2 at %.

The low oxygen content in the layer prevents a formation of oxynitrides which would have a detrimental impact on the crystal growth and in particular on the formation of a preferred orientation of the crystal structure.

The properties of the high refractive index hard material layer described above and hence of the anti-reflective coating may in particular be achieved if the hard material layer is applied by a sputtering process.

The high refractive index hard material layer may be a pure aluminum nitride layer, or the hard material layer may include other components in addition to the aluminum nitride, for example one or more other nitrides, carbides and/or carbonitrides. Preferably, the nitrides, carbides or carbonitrides comprise respective compounds of elements selected from a group comprising silicon, boron, zirconium, titanium, nickel, chromium, and carbon.

This doping permits to further modify properties of the hard material layer such as hardness, modulus of elasticity, and abrasion resistance, e.g. resistance to polishing.

In order to ensure that a crystalline aluminum nitride phase is formed in these embodiments, an aluminum content of the hard material layer of >50 wt %, preferably >60 wt %, and more preferably >70 wt %, is especially advantageous, based on the additional elements silicon, boron, zirconium, titanium, nickel, chromium, and/or carbon in each case.

Respective mixed layers are referred to as doped AlN layers in the context of the invention. The compounds included in addition to AlN are referred to as a dopant, and the content of dopants may be up to 50 wt %. Even layers having a dopant content of up to 50 wt % are regarded as doped layers in the context of the invention.

In mixed layers, i.e. doped AlN layers, AlN crystallites are embedded in a matrix of the dopant. The degree of crystallization of the layer may therefore be adjusted through the amount of the dopant in the mixed layer. Moreover, the crystallite size is limited by the matrix. A crystallite size of not more than 20 nm, preferably not more than 15 nm has been found particularly advantageous. In particular, the average size of the AlN crystallites is in a range from 5 to 15 nm. This crystallite size ensures high transmittance and mechanical resistance of the hard material layer.

In one embodiment of the invention, the high refractive index hard material layer contains boron nitride in addition to the aluminum nitride, i.e. the layer is doped with boron nitride. Due to the boron nitride included, the friction coefficient of the layer is reduced, which in particular results in a higher resistance of the layer to polishing processes. This is advantageous both in terms of the resistance of a respective coated substrate when being used by the end user and in terms of possible process steps during the further processing of the coated substrate.

In another embodiment of the invention, the high refractive index hard material layer is doped with silicon nitride, i.e. an AlN:SiN material system is provided which allows to influence individual properties such as adhesion, hardness, roughness, the friction coefficient, and/or thermal stability. According to one modification of this embodiment, the hard material layer includes in addition to silicon nitride at least one further of the aforementioned components. Furthermore, the coefficient of thermal expansion of the hard material layer may be influenced by the type and amount of the dopant used, or may be adapted to the substrate.

Thus, glasses can be used as substrates, in particular sapphire glasses, borosilicate glasses, aluminosilicate glasses, lime-soda glasses, synthetic quartz glasses (known as fused silica glasses), lithium aluminosilicate glasses, optical glasses, or glass ceramics. Crystals for optical applications, such as potassium fluoride crystals, may also be used as the substrate. In one embodiment of the invention the substrate is a toughened glass, in particular a chemically or thermally tempered glass.

It has been found particularly advantageous to use the coating of the invention as a scratch-resistant layer on a sapphire glass. Substrates coated accordingly are ideal for use as a cover glass on watches.

Preferably, the substrates have a coefficient of thermal expansion [symbol] −300 in a range from 7*10−6 to 10*10−6 K−1. This is advantageous since in such an embodiment the substrate and the coating will have very similar thermal expansion coefficients.

However, substrates with different coefficients of thermal expansion may also be coated without departing from the scope of the invention. For example, according to one embodiment of the invention the substrate is a glass ceramic, in particular a glass ceramic having a coefficient of thermal expansion [symbol] −300 of smaller than 1*10−6 K−1.

Furthermore, the coatings of the invention are permanently stable to temperatures of at least 300° C., preferably at least 400° C. Thus, a substrate coated according to the invention may be used for example as an oven viewing window or a cooktop. Due to the high temperature stability of the coating, the coating may even be applied to the hot zones of the cooktop.

Often, a decor is printed on a glass ceramic surface, in particular in case of cooktops. Therefore, according to one embodiment it is suggested that the substrate is provided with a decorative layer, at least partly, and that the decorative layer is arranged between the substrate and the coating. Due to the high transmittance of the coating according to the invention the decor is well perceived through the coating. In addition, the decorative layer is protected from mechanical stresses by the hard material layer, so that less stringent requirements in terms of mechanical strength need to be imposed on the decorative layer. In contrast to pure scratch-protection layers, anti-reflective scratch-resistant coatings for cooktops have the advantage that the coated cooktops are visually less obtrusive and thus polishing stress is less noticeable.

Depending on the application and the substrate employed, the coating may be a layer system comprising three or more dielectric layers. In the context of the invention, dielectric layer particularly refers to a low or high refractive index layer that contributes to an anti-reflective effect of the coating. To ensure an anti-reflective effect, the uppermost dielectric layer is a low refractive index layer.

The inventive coating exhibits a good anti-reflective effect and at the same time high mechanical strength and wear resistance. The high mechanical strength can be seen, for example, from the fact that after having been subjected to mechanical stress according to the so-called Bayer test, residual reflectance at a wavelength of 750 nm has changed by not more than 35%, preferably by not more than 25%, as compared to the reflectance of the uncoated substrate. By contrast, optical interference coatings known from prior art show a change by approximately 50% as compared to the uncoated substrate. In the Bayer test a coated substrate having a diameter of 30 mm is loaded with 90 g of sand which is then moved on the substrate for a period of about 1 hour, in 13,500 oscillations.

In an advantageous embodiment of the invention, residual reflectance of the coated substrate after the Bayer test is less than 5%, preferably less than 3%, and most preferably less than 2.5%, at a wavelength of 750 nm.

Another measure for the high mechanical strength of a substrate coated according to the invention is haze of the coating following the Bayer test, which haze is determined in accordance with ASTM D1003, D1044. After the Bayer test, the coated substrate preferably exhibits haze which is higher by a maximum of 5% or even only by a maximum of 3% than the haze of the coated substrate before the Bayer test.

According to one embodiment, the coating comprises three dielectric layers. In this case, the coating comprises a first and a second low refractive index layer and one high refractive index hard material layer. The first low refractive index layer is disposed between the substrate and the high refractive index hard material layer, and the second low refractive index layer is disposed on the high refractive index hard material layer. The layer thickness of the first low refractive index layer is preferably in a range from 5 to 50 nm, more particularly in a range from 10 to 30 nm, the layer thickness of the second low refractive index layer is in a range from 40 to 120 nm, preferably in a range from 60 to 100 nm. Thus, the layer thickness of the second or upper low refractive index layer is greater than the thickness of the first low refractive index layer, since the second low refractive index layer will be exposed to greater mechanical stress than the first low refractive index layer. The layer thickness of the high refractive index hard material layer is preferably in a range from 80 to 1200 nm, more particularly in a range from 100 to 1000 nm, preferably in a range from 100 to 700 nm. According to one embodiment of the invention, the hard material layer has a thickness of less than 500 nm, preferably less than 400 nm, and most preferably less than 200 nm. Hard material layers of such thicknesses ensure high mechanical resistance of the coating and at the same time a high anti-reflective effect.

According to one modification of the invention, the coating comprises at least 5 dielectric layers. In this case, the coating comprises a first, a second, and a third low refractive index layer, and a first and a second high refractive index hard material layer. Low refractive index layers and high refractive index layers are arranged alternately, the bottom layer and the uppermost layer being low refractive index layers.

Thus, the first low refractive index layer is disposed between the substrate and the first high refractive index hard material layer, the second low refractive index layer is disposed between the first and the second high refractive index hard material layers, and the third low refractive index layer is disposed on the second high refractive index hard material layer. Preferably, the first low refractive index layer has a layer thickness in a range from 10 to 60 nm, the second low refractive index layer has a layer thickness in a range from 10 to 40 nm, the third low refractive index layer has a layer thickness in a range from 60 to 120 nm, the first high refractive index hard material layer has a layer thickness in a range from 10 to 40 nm, and/or the second high refractive index hard material layer has a layer thickness in a range from 100 to 1000 nm.

According to an advantageous embodiment of the invention, the layer thickness of the entire coating is at most 600 nm or even less than 600 nm. The small layer thickness provides for high transmittance of the coating, moreover the coatings are neutral in color, i.e. the coating has a colorless appearance. Thicker coatings, by contrast, may have a color cast. Thus, in particular with the embodiment described above a colorless design of the coating is possible. Another advantage of a thin coating is that even with thin substrates there will be only little or no warp. Warp is more pronounced the smaller the ratio of layer thickness of the substrate to layer thickness of the coating. Thus, thin substrates with a relatively thick coating will exhibit more warp than similar substrates with a thin coating, for example.

The coating of the invention or the substrate coated according to the invention exhibit good mechanical strength and scratch resistance even in case of a small total thickness. This is mainly attributable to the hard material layer.

The substrate coated according to the invention may be used in particular as an optical component, a cooktop, a viewing window in the automotive sector, for watch glasses, oven viewing windows, glass or glass ceramic components in household appliances, or as a display, e.g. for tablet PCs and cell phones, especially as a touch display.

Furthermore, the invention relates to a method for manufacturing the substrate coated according to the invention. The method comprises at least the steps of:
a) providing a substrate;
b) coating the substrate with a low refractive index SiO2 containing layer;
c) providing the substrate as coated in step b) in a sputtering apparatus that includes an aluminum containing target;
d) releasing sputtered particles at a power density in a range from 8 to 1000 W/cm2, preferably from 10 to 100 W/cm2 per target surface; and
e) depositing a further low refractive index SiO2 containing layer onto the coated substrate as obtained in step d).

The substrate provided in step a) may be, for example, a glass, in particular a sapphire glass, a borosilicate glass, an aluminosilicate glass, a soda-lime glass, a synthetic quartz glass, a lithium aluminosilicate glass, an optical glass, a glass ceramic, and/or a crystal for optical purposes.

The low refractive index layer may be applied by a sputtering process, a sol-gel process, or by CVD technology.

The deposition of the high refractive index hard material layer onto the substrate provided with a low refractive index layer as obtained in step b) is performed in step d) only at comparatively low final pressures. For example, the final pressure in the coating apparatus, i.e. the pressure at which a coating process can be started, is at most 2*10−5 mbar, preferably even in a range from 1*10−6 to 5*10−6 mbar. Due to the low final pressures, the amount of foreign gas is minimized, which means that the coating process is performed in a very clean atmosphere. This ensures a high purity of the deposited layers. Thus, due to the process-related low residual gas content, a formation of oxynitrides caused by incorporation of oxygen is avoided. This is of particular importance in view of the crystal growth of the AlN crystallites which would be affected by oxynitrides. Thus, preferably, a coating may be obtained which has an oxygen content of not more than 10 at %, more preferably not more than 5 at %, or even less than 2 at %. By contrast, in conventional sputtering processes the final pressure during the coating process is in a range of at least 5*10−5 mbar, accordingly the proportion of oxygen in the deposited coating will be higher in this case.

In one embodiment of depositing the hard material layer, during the sputtering process, once the final pressure according to the invention has been reached a nitrogen-containing process gas is introduced. The proportion of nitrogen in the total gas flow is at least 30 vol %, preferably 40 vol %, more preferable 50 vol %. Through the nitrogen proportion in the total gas flow during the sputtering process it is possible to influence the chemical resistance of the deposited layer, for example to detergents or cleaning agents. The resistance of the layer against chemicals increases as the nitrogen content increases.

The deposition of the high refractive index layer in step d) is performed at high sputtering powers. In the method according to the invention, sputtering powers are at least from 8 to 1000 W/cm², preferably at least from 10 to 100 W/cm². In one embodiment of the invention, a high power impulse magnetron sputtering (HiPIMS) process is employed. Alternatively or additionally, a negative voltage or an AC voltage may be maintained between the target and the substrate.

Alternatively or additionally, the deposition of the high refractive index layer in step d) may be performed with ion bombardment assistance, preferably ion bombardment from an ion beam source, and/or by applying a voltage to the substrate.

The sputtering process may be performed with continuous deposition. Alternatively, the hard material layer may consist of interfaces that arise due to the processing upon retraction from the coating zone.

By a subsequent treatment in a further process step, crystal formation in the AlN coating may be further enhanced. In addition, individual properties such as the coefficient of friction can be beneficially influenced by a post-treatment. Post-treatment processes contemplated include laser treatment or several thermal treatments, e.g. irradiation with light. Ion or electron implantation is likewise conceivable.

According to one embodiment, the particles generated by sputtering are deposited at a temperature above 100 ° C., preferably above 200 ° C., and more preferably above 300 ° C. In this way in combination with the low processing pressures and the high sputtering powers, the growth of AlN crystallites especially in terms of crystallite size and preferred orientation of the crystal structure may be influenced in a particularly advantageous manner. However, a deposition at lower temperatures, for example at room temperature, is also possible. The hard material layers produced according to this embodiment also exhibit good mechanical properties, such as high scratch resistance.

In one embodiment of the invention, the target contains in addition to aluminum at least one of the elements silicon, boron, zirconium, titanium, nickel, chromium, or carbon. These additional elements in addition to aluminum are referred to as a dopant in the context of the invention. Preferably, the proportion of aluminum in the target is greater than 50 wt %, more preferably greater than 60 wt %, and most preferably greater than 70 wt %.

In one embodiment of the invention, the processing sequence comprising steps c) to d) is performed several times. In this manner, coatings comprising five or more dielectric layers may be obtained, for example.

According to one embodiment of the invention, the anti-reflective coating is deposited on a substrate having a roughened or etched surface.

According to one variation of the manufacturing method, the substrate provided in step a) already has a high refractive index hard material layer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The invention will now be described by way of exemplary embodiments and with reference to FIGS. 1 to 11, wherein:

FIG. 1 and FIG. 2 are schematic diagrams of two embodiments of substrates coated according to the invention;

FIG. 3 shows the change in reflectance caused by a Bayer test, for an embodiment of the invention and for a comparative example;

FIG. 4 shows reflection characteristics of a first exemplary embodiment and of a comparative example before and after subjection to the Bayer test;

FIG. 5 shows reflection characteristics of a second exemplary embodiment and of a comparative example before and after subjection to the Bayer test;

FIG. 6 is an EDX spectrum of a high refractive index hard material layer;

FIGS. 7a and 7b are TEM images of two AlN:SiN mixed layers having different AlN contents;

FIG. 8 is an XRD spectrum of an exemplary embodiment of a high refractive index hard material layer;

FIG. 9 shows XRD spectra of two AlN hard material layers exhibiting different preferred orientations;

FIGS. 10a to 10c are photographs of different coated substrates with high refractive index hard material layers exhibiting different preferred orientations, after a mechanical stress test with sand; and

FIGS. 11a and 11b are photographs of different coated substrates with high refractive index hard material layers exhibiting different preferred orientations of the crystal structure, after a mechanical stress test with silicon carbide.

### DETAILED DESCRIPTION

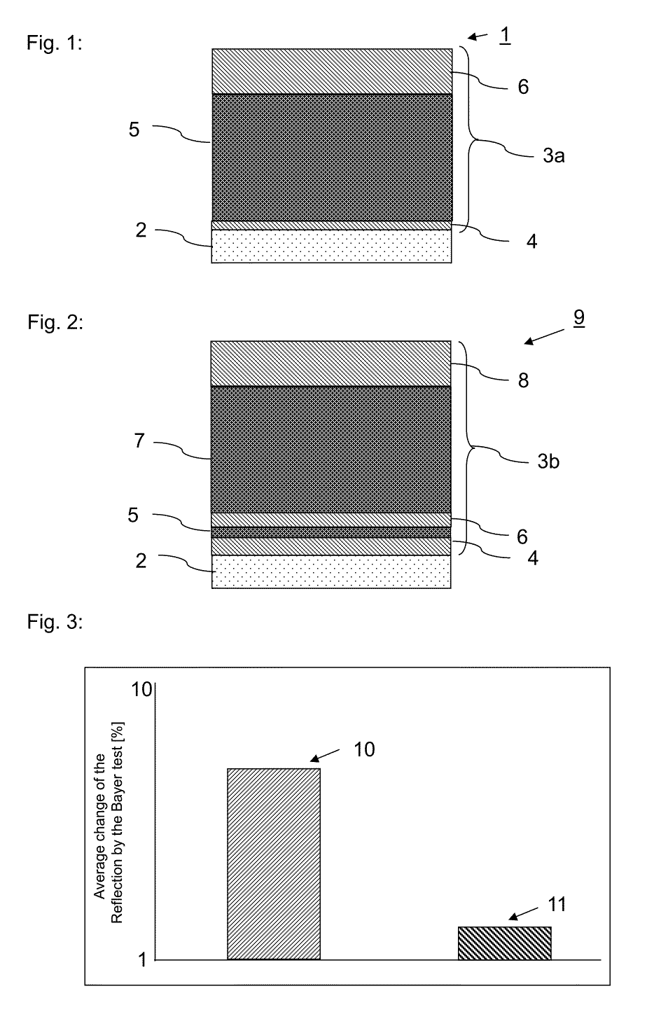

FIG. 1 schematically shows an exemplary embodiment of a substrate coated according to the invention 1. Here, substrate 2 is coated with a three-layered optical interference coating 3a. Coating 3a comprises layers 4, 5, and 6. Layers 4 and 6 are low refractive index layers, layer 5 is a high refractive index layer. The first low refractive index layer 4 is deposited directly on the substrate 2 and has a layer thickness in a range from 10 to 30 nm. On first low refractive index layer 4, the first high refractive index layer 5 is arranged, which has a layer thickness from 100 to 1000 nm. First high refractive index layer 5 is disposed between the first low refractive index layer 4 and the second low refractive index layer 6. In the embodiment shown in FIG. 1, the second low refractive index layer 6 forms the uppermost layer of coating 3a and has a layer thickness in a range from 60 to 100 nm. Thus, the thickness of the second low refractive index layer 6 is greater than the thickness of the first low refractive index layer 4, since the second low refractive index layer 6 is the uppermost layer of coating 3a and will be exposed to greater mechanical stress. The thickness of the first high refractive index layer 5 is not only adapted to optical requirements for creating a layer system that has an anti-reflective effect, but moreover substantially contributes to the mechanical strength of the entire coating 3a and thus of the coated substrate 1.

FIG. 2 is a schematic diagram of a second exemplary embodiment 9. In this exemplary embodiment, the substrate 2 is provided with a five-layered coating 3b. In addition to the first and second low refractive index layers (4, 6) and the first high refractive index layer 5, coating 3b comprises a second high refractive index layer 7 and a third low refractive index layer 8. Here, the second high refractive index layer 7 is disposed between the second and third low refractive index layers (6, 8). In exemplary embodiment 9, the third low refractive index layer 8 is the uppermost layer of the coating and has a layer thickness in a range from 60 to 120 nm. The layer thickness of the first low refractive index layer 4 is in a range from 10 to 60 nm, and the layer thickness of the second low refractive index layer 6 is in a range from 10 to 40 nm. In this embodiment, since the mechanical strength of coating 3b is mainly ensured by the second high refractive index layer 7, the first high refractive index layer 5 has a smaller thickness from 10 to 40 nm, while the layer thickness of the second high refractive index layer is in a range from 100 to 1000 nm.

FIG. 3 shows the average change of reflectance of a substrate coated according to the invention 11 and of a comparative example 10 following a Bayer test. For this purpose, each sample having a size of 30 mm in diameter was loaded with 90 g of sand and was subjected to 13,500 oscillations. Subsequently, reflectance of the so treated samples was determined using a spectrometer and was compared to the reflectance of an untreated sample. Comparative sample 10 was a coated substrate as described in DE 10 2011 012 160. As can be seen from FIG. 3, caused by the mechanical stress the reflectance of comparative sample 10 changed to a significantly greater degree than is the case with the substrate coated according to the invention 11. The anti-reflective coating of sample 11 is much more resistant to mechanical stress such as scratches, as simulated by the Bayer test, than anti-reflective coatings known from prior art.

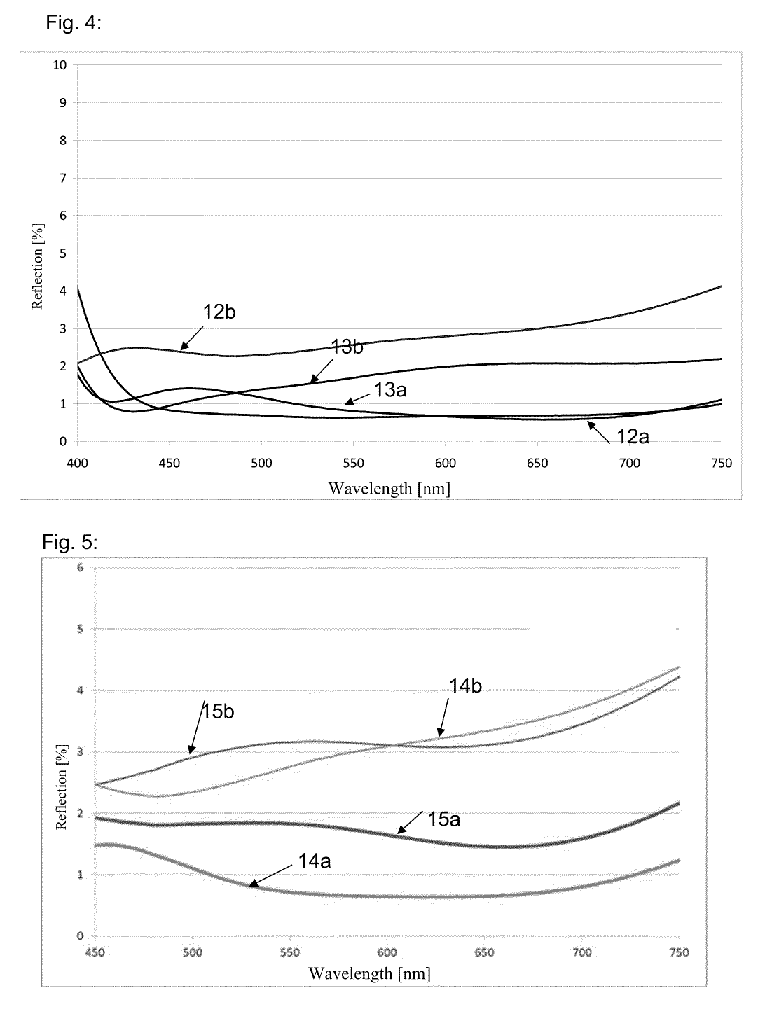

FIG. 4 shows reflectance characteristics as a function of wavelength of an exemplary embodiment and of a comparative example before and after a Bayer test. The comparative example 12 is a coated substrate as described in DE 10 2011 012 160. The five-layered coating of exemplary embodiment 13 includes low refractive index SiO2 layers. The high refractive index layers are aluminum nitride layers doped with silicon (AlN:SiN). Curves 12a and 13a show the reflectance characteristics of the comparative example and of the exemplary embodiment before the Bayer test. The reflectance characteristics after the Bayer test described above are shown by curves 12b (comparative example) and 13b (exemplary embodiment). While before the Bayer test the comparative sample and the exemplary embodiment have similar reflectance characteristics, after the Bayer test the comparative example exhibits a significantly higher reflectance than the exemplary embodiment, over the whole range of wavelengths measured.

FIG. 5 shows the reflectance as a function of wavelength of a comparative example (14a, 14b) and of a further embodiment (15a, 15b) before and after a Bayer test. The coating of this embodiment comprises low refractive index layers of a composition SiAlOx. As can be clearly seen from curves 14a and 15a, before the Bayer test the exemplary embodiment (curve 15a) has a higher residual reflectance than the comparative example (curve 14a). However, due to the Bayer test, the reflectance of the comparative example (curve 14b) increases much more than that of the exemplary embodiment (curve 15b). Moreover, it can be observed in the comparative example that the increase in reflectance becomes greater as the wavelength increases. Thus, after the Bayer test, for wavelengths of about 600 nm and larger, the comparative sample exhibits a higher reflectance than the similarly treated exemplary embodiment. In addition, with the exemplary embodiment the change in reflectance is not or only slightly dependent on the wavelength, so that after the Bayer test a substantially constant change in reflectance is observed over the entire measured range of wavelengths. This is particularly advantageous since in this manner the color appearance of the coating is largely maintained.

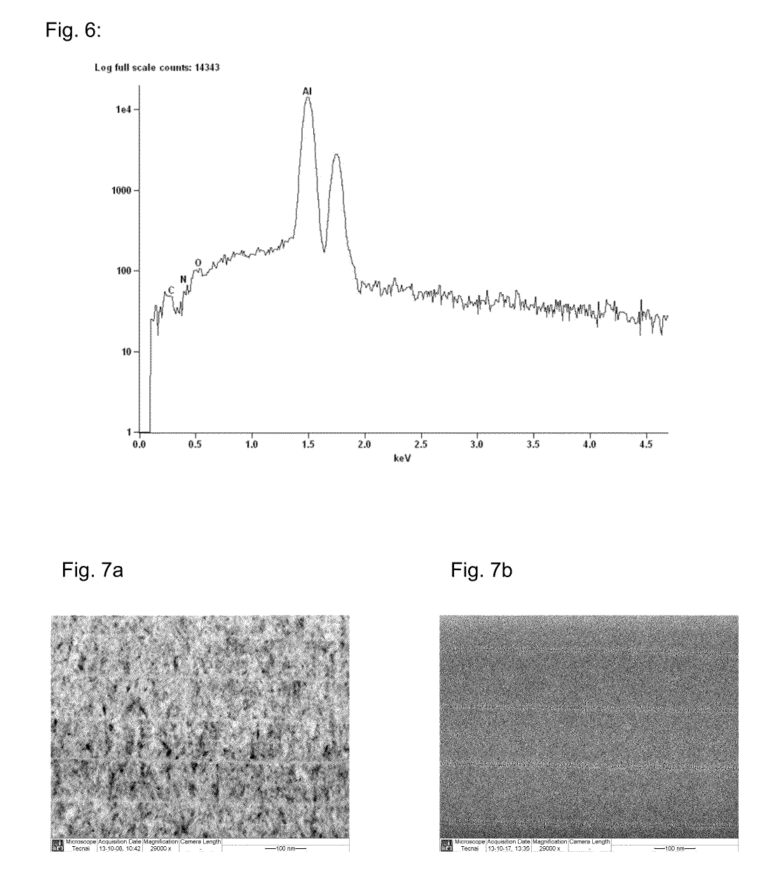

FIG. 6 shows a spectrum of energy dispersive X-ray (EDX) spectroscopy or energy dispersive x-ray analysis of a hard material layer such as provided as the high refractive index layer in the coating according to the invention. The hard material layer in this exemplary embodiment is an AlN layer alloyed with silicon.

FIG. 7a shows a transmission electron micrograph (TEM) of a high refractive index hard material layer according to the invention. The TEM image shown in FIG. 7a is a micrograph of an AlN layer doped with SiN, i.e. an AlN:SiN layer, with a content of AlN of 75 wt % and a content of SiN of 25 wt %. As can be seen from FIG. 7a, the AlN of the hard material layer is crystalline and is embedded an SiN matrix. By contrast, an AlN:SiN layer which comprises AlN and SiN in equal proportions will be amorphous. A TEM image of a corresponding layer is shown in FIG. 7b. Here, the high content of SiN prevents a formation of AlN crystallites.

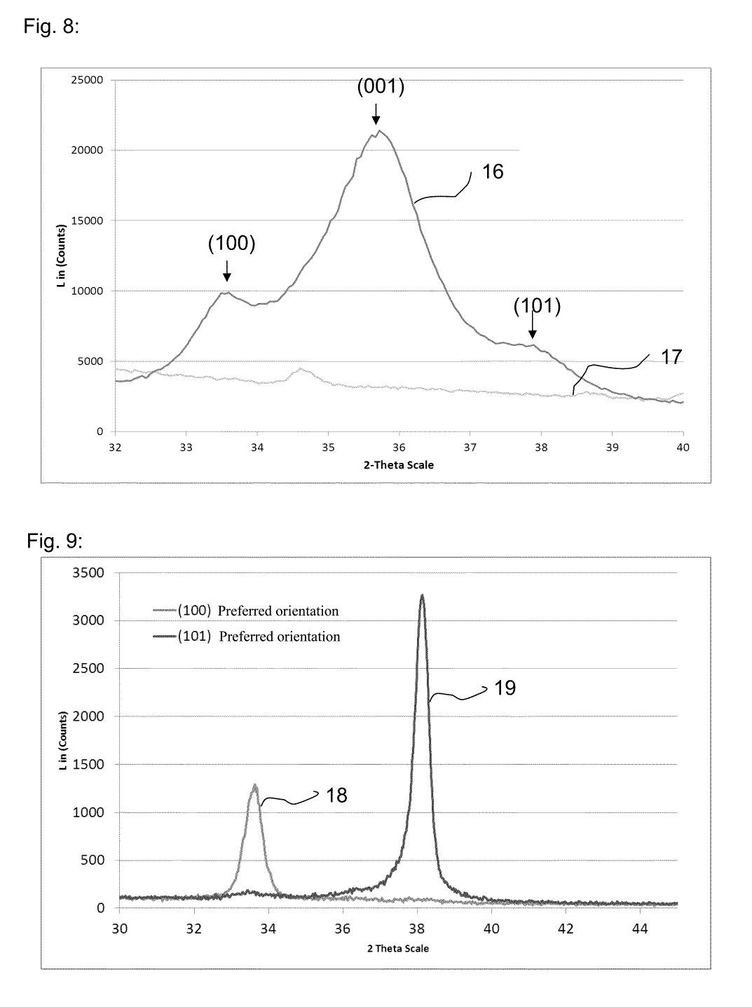

FIG. 8 shows an X-ray diffraction (XRD) spectrum of an exemplary embodiment of a substrate provided with a high refractive index hard material layer. For this purpose, an SiO2 substrate was coated with an AlN:SiN hard material layer, and an XRD spectrum of the coated substrate was acquired. Spectrum 16 has three reflections that can be associated with the three orientations (100), (001), and (101) of the hexagonal crystal structure of AlN. It can clearly bel seen that the hard material layer has a predominant (001) preferred orientation. The corresponding reflection at 36° is much more pronounced than the reflections of the (100) orientation (33.5°) and of the (101) orientation (38°).

The proportion of the crystal structure exhibiting the (001) preferred orientation can be determined from spectrum 16 as follows:

| I(001) [counts] | I(100) [counts] | I(010) [counts] |
|---|---|---|
| 21,000 | 10,000 | 6,000 |

x(001)=I(001)/(I(001)+I(100)) and

y(001)=I(001)/(I(001)+I(101))

In this high refractive index layer, fraction x(001) is 0.67, and fraction y(001) is 0.77.

Measurement curve 17 is an XRD spectrum of the uncoated substrate.

The hard material layer was deposited at a sputtering power in a range of more than 15 W/cm² with a low target/substrate spacing ranging from 10 to 12 cm. Processing temperature was 250° C.

FIG. 9 shows XRD spectra of hard material layers which have a similar composition as that of the exemplary embodiment shown in FIG. 8, but exhibit other preferred orientations of the crystal structure. Spectrum 18 can be associated with a comparative example having a (100) preferred orientation, and spectrum 19 can be associated with a comparative example having a (101) preferred orientation.

The hard material layer exhibiting the (100) preferred orientation (curve 19) was deposited with a comparatively high target/substrate spacing (>15 cm) and lower sputtering power of 13 W/cm2 (curve 19). Processing temperature was about 100° C. The hard material layer exhibiting the (101) preferred orientation (curve 18) was obtained under similar processing conditions, but with an even lower sputtering power of 9.5 W/cm².

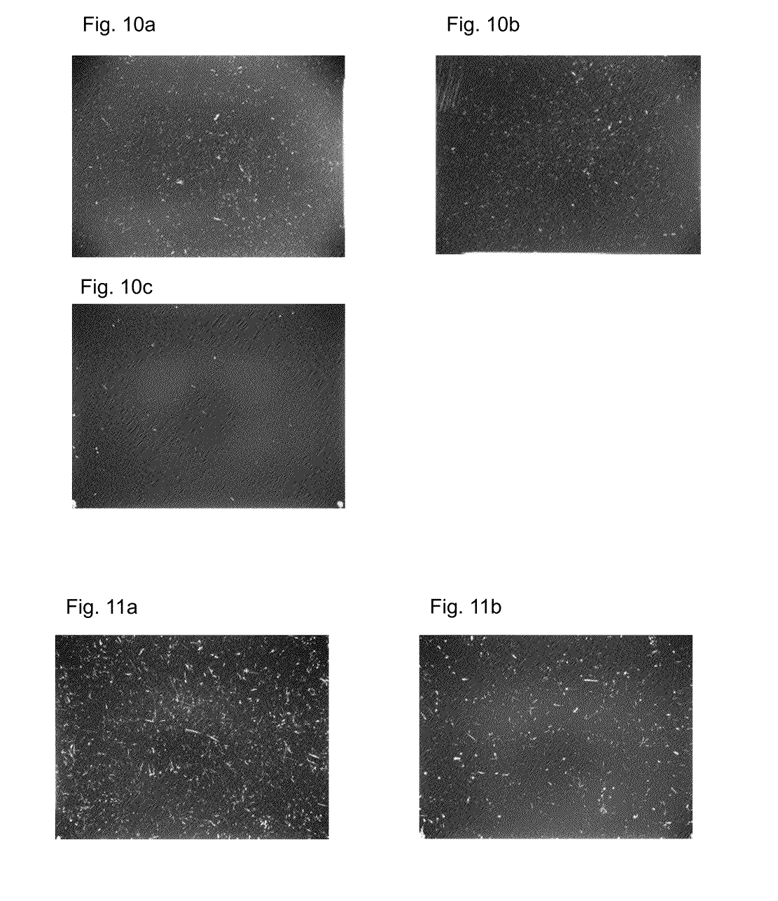

From FIGS. 10a to 10c, the influence of the preferred orientation of the crystal structure on the mechanical resistance of the respective hard material layers can be seen. FIGS. 10a to 10c are photographs of substrates provided with high refractive index hard material layers exhibiting different preferred orientations, after a stress test with sand in which sand was placed on the coated substrates and was then loaded with load bodies and oscillated 100 times in a container. FIG. 10a shows a photograph of a sample having a coating with (101) preferred orientation following the stress test, FIG. 10b shows a corresponding photograph of a sample with (100) preferred orientation, and FIG. 10c shows a photograph of a sample with (001) preferred orientation. As can be clearly seen from FIGS. 10a to 10c, the samples exhibiting the (101) and (100) preferred orientations have a much higher number of scratches after the stress test than the sample having a (001) preferred orientation. The sample shown in FIG. 10c is the same embodiment as that of the XRD spectrum illustrated in FIG. 8.

FIGS. 11a and 11b show substrates provided with a high refractive index hard material layer after a mechanical stress test using SiC. This stress test in particular simulates the resistance to very hard materials and the cleanability under any cleaning agents and auxiliary means. The test procedure is similar to that of the sand test. In this example, the coating of the sample shown in FIG. 11a does not exhibit a (001) orientation of the crystallites, while the coating of the sample shown in FIG. 11b exhibits a predominant (001) orientation. When comparing FIGS. 11a and 11b it can clearly be seen that the sample with predominant (001) orientation has significantly less scratches than the sample without predominant (001) orientation of the crystallites.

What is claimed is:

1. A coated substrate comprising:
a substrate; and
an anti-reflective coating designed as an optical interference coating including at least two low refractive index layers and at least one high refractive index layer,
the high refractive index layer being a transparent hard material layer that comprises crystalline aluminum nitride having a hexagonal crystal structure exhibiting a predominant (001) preferred orientation, wherein the at least two low refractive index layers include SiO2, and wherein the high refractive index layer is disposed between the at least two low refractive index layers.

2. The coated substrate as claimed in claim 1, wherein the at least two low refractive index layers comprise SiO2 and/or doped SiO2.

3. The coated substrate as claimed in claim 2, wherein the at least two low refractive index layers further comprise Al as a dopant.

4. The coated substrate as claimed in claim 2, wherein at least the two low refractive index layers comprise at least one low refractive index layer that is doped with one or more oxides and/or nitrides and/or carbides and/or carbonitrides of elements selected from the group consisting of silicon, boron, zirconium, titanium, nickel, chromium, and carbon.

5. The coated substrate as claimed in claim 1, wherein at least the two low refractive index layers comprise at least one low refractive index layer that is doped with one or more oxides and/or nitrides and/or carbides and/or carbonitrides of elements selected from the group consisting of silicon, boron, zirconium, titanium, nickel, chromium, and carbon.

6. The coated substrate as claimed in claim 1, wherein the at least two low refractive index layers have a refractive index at a wavelength of 550 nm ranging from 1.3 to 1.6 and the high refractive index layer has a refractive index at a wavelength of 550 nm ranging from 1.8 to 2.3.

7. The coated substrate as claimed in claim 1, wherein proportions of the crystal structure exhibiting a (001) preferred orientation, x(001) and y(001), with
x(001)=I(001)/(I(001)+I(100)), and
y(001)=I(001)/(I(001)+i(101)), as determined by an XRD measurement, are greater than 0.5.

8. The coated substrate as claimed in claim 1, wherein the high refractive index layer has a modulus of elasticity at a test load of 10 mN ranging from 80 to 250 GPa.

9. The coated substrate as claimed in claim 8, wherein the high refractive index layer has a ratio of hardness to the modulus of elasticity of at least 0.08.

10. The coated substrate as claimed in claim 1, wherein the high refractive index layer has a ratio of hardness to a modulus of elasticity of at least 0.08.

11. The coated substrate as claimed in claim 1, wherein the hard material layer has a total layer thickness of at most 600 nm.

12. The coated substrate as claimed in claim 1, wherein the hard material layer has a proportion of oxygen that is at most 10 at %.

13. The coated substrate as claimed in claim 1, wherein the hard material layer has a proportion of oxygen that is less than 2 at %.

14. The coated substrate as claimed in claim 1, wherein the substrate is selected from the group consisting of glass, chemically glass, thermally tempered glass, sapphire glass, borosilicate glass, aluminosilicate glass, soda-lime glass, synthetic quartz glass, lithium aluminosilicate glass, optical glass, crystal, and glass ceramic.

15. The coated substrate as claimed in claim 1, wherein, after having been subjected to a Bayer test with a load of 90 g of sand and 13,500 oscillations, the coated substrate exhibits a residual reflectance at a wavelength of 750 nm of less than 5% and/or exhibits a haze which is greater than prior to the stress test by not more than 5%.

16. The coated substrate as claimed in claim 1, wherein the anti-reflective coating comprises three dielectric layers in form of a first and a second low refractive index layer and one high refractive index hard material layer, wherein the first low refractive index layer is disposed between the substrate and the high refractive index hard material layer and the second low refractive index layer is disposed on the high refractive index hard material layer, wherein the first low refractive index layer has a layer thickness in a range from 5 to 50 nm, the second low refractive index layer has a layer thickness in a range from 40 to 120 nm, and the high refractive index hard material layer has a layer thickness in a range from 80 to 1200 nm.

17. The coated substrate as claimed in claim 1, wherein the anti-reflective coating comprises at least five dielectric layers in the form of a first, a second, and a third low refractive index layer, and a first and a second high refractive index hard material layer, wherein the first low refractive index layer is disposed between the substrate and the first high refractive index hard material layer, the second low refractive index layer is disposed between the first and the second high refractive index hard material layers, and the third low refractive index hard material layer is disposed on the second high refractive index hard material layer, and wherein the first low refractive index layer has a layer thickness in a range from 10 to 60 nm, the second low refractive index layer has a layer thickness in a range from 10 to 40 nm, the third low refractive index layer has a layer thickness in a range from 60 to 120 nm, the first high refractive index hard material layer has a layer thickness in a range from 10 to 40 nm, and the second high refractive index hard material layer has a layer thickness in a range from 100 to 1000 nm.

18. A method for producing a coated substrate having an anti-reflective coating, comprising:
a) providing a substrate;
b) coating the substrate with a low refractive index SiO2 containing layer;
c) providing the substrate as coated in step b) in a sputtering apparatus that includes an aluminum containing target;
d) releasing sputtered particles at a power density in a range from 8 to 1000 W/cm2 per target surface and at a final pressure of not more than 2*10−5 mbar; and
e) depositing a further low refractive index SiO2 containing layer onto the coated substrate as obtained in step d).

19. The method as claimed in claim 18, wherein step a) comprises providing a substrate having a high refractive index hard material layer.

20. The method as claimed in claim 18, wherein the sequence of process steps c) to e) is more than one time.
